(19) United States
(12) Patent Application Publication
(10) Pub. No.: US 2024/0250149 A1
(43) Pub. Date: Jul. 25, 2024

(54) FLASH MEMORY AND METHOD FOR FORMING THE SAME

(71) Applicant: Winbond Electronics Corp., Taichung City (TW)

(72) Inventors: Yung-Han CHIU, Taichung City (TW); Wen-Chieh TSAI, Taichung City (TW); Shu-Ming LI, Taichung City (TW)

(21) Appl. No.: 18/416,033

(22) Filed: Jan. 18, 2024

(30) Foreign Application Priority Data
Jan. 19, 2023 (TW) 112102633

(51) Int. Cl. H01L 29/66; H10B 41/30; H10B 43/30

(52) U.S. Cl. CPC H01L 29/6656; H10B 41/30; H10B 43/30

(57) ABSTRACT

A flash memory includes multiple gate stacks arranged on a substrate, and a spacer structure. The spacer structure includes multiple thin spacers covering sidewalls of lower portions of the gate stacks and multiple thick spacers covering sidewalls of upper portions of the gate stacks. The thick spacers are located over the respective thin spacers, and the thick spacers are thicker than the thin spacers. The flash memory also includes a dielectric structure disposed on the spacer structure, and an air gap sealed by the dielectric structure and the spacer structure. The air gap includes a body portion between the thin spacers and a head portion between the thick spacers, and the body portion is wider than the head portion.

### CROSS REFERENCE TO RELATED APPLICATIONS

This application claims the benefit of Taiwan patent application Ser. No. 11/210,2633 filed on Jan. 19, 2023, entitled “FLASH MEMORY AND METHOD FOR FORMING THE SAME” which is hereby incorporated herein by reference.

### BACKGROUND

### Field of the Disclosure

The present disclosure relates to a flash memory, and in particular, it relates to a gate spacer structure of the flash memory for forming a wider air gap.

### Description of the Related Art

In order to increase the component density and improve the overall performance of flash memory devices, current manufacturing techniques are continuously striving towards miniaturization of component sizes. However, as flash memory devices shrink in size, the spacing of adjacent word lines (or gates) becomes closer, resulting in a higher likelihood of coupling effects between neighboring floating gates. For conventional flash memory devices, the thickness of the spacers between word lines increases to mitigate the coupling effects between floating gates. However, this approach hinders miniaturization.

So, the industry still needs to improve the methods of manufacturing flash memory devices to overcome the issues arising from the reduction in component size.

### SUMMARY

The embodiments of the present disclosure provide a flash memory and a method for forming the same, which can improve the issues that are not conducive to miniaturization and the coupling effect that is prone to occur between adjacent floating gates.

A flash memory includes multiple gate stacks arranged on a substrate, a spacer structure, a dielectric structure disposed on the spacer structure, and an air gap sealed by the dielectric structure and the spacer structure. The spacer structure includes multiple thin spacers covering sidewalls of lower portions of the gate stacks and multiple thick spacers covering sidewalls of upper portions of the gate stacks. The thick spacers are located over the respective thin spacers, and the thick spacers are thicker than the thin spacers. The thick spacers comprise upper portions of a first spacer layer and second spacer layers, the thin spacers comprise lower portions of the first spacer layer, and the lower portions of the first spacer layer are thinner than the upper portions of the first spacer layer. The air gap includes a body portion between the thin spacers and a head portion between the thick spacers, and the body portion is wider than the head portion.

The method of forming a flash memory includes forming multiple gate stacks over a substrate, conformally forming a first spacer layer on sidewalls of the gate stacks, forming a sacrificial layer to partially fill a trench between the gate stacks and cover a lower portion of the first spacer layer, forming a second spacer layer to cover an upper portion of the first spacer layer and an upper surface of the sacrificial layer, removing a horizontal portion of the second spacer layer covering the upper surface of the sacrificial layer, completely removing the sacrificial layer, partially removing the lower portion of the first spacer layer to form a thin spacer, and forming a dielectric structure on a top surface of the first spacer layer and a top surface of the second spacer layer. The trench is sealed by the dielectric structure to form an air gap.

According to the embodiments of the present disclosure, due to the larger volume of the body portion of the air gap, there can be a lower capacitance between the floating gates of adjacent gate stacks. As a result, it is possible to mitigate the coupling effect between floating gates and improve the data retention capability of memory cells, thereby enhancing the performance of the resulting flash memory.

### BRIEF DESCRIPTION OF THE DRAWINGS

FIGS. 1 to 8 illustrate cross-sectional views of forming a flash memory at various stages, in accordance with some embodiments of the present disclosure.

### DETAILED DESCRIPTION

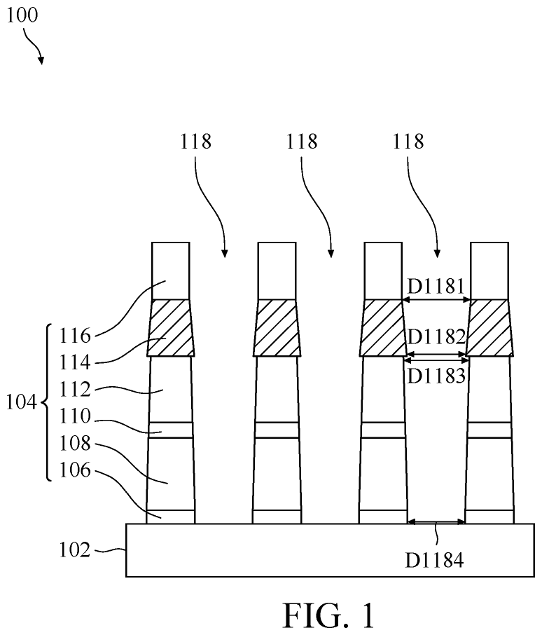

The present disclosure is described in detail with reference to the figures of the embodiments. The same or similar reference numbers in the figures are denoted as the same or similar elements. According to some embodiments of the present disclosure, as shown in FIG. 1, a flash memory 100 includes multiple gate stacks 104 formed over a substrate 102. In some embodiments, the substrate 102 may be an elemental semiconductor substrate, such as a silicon or germanium substrate, or a compound semiconductor substrate, such as a silicon carbide or gallium arsenide substrate. In some embodiments, the substrate 102 may be a semiconductor-on-insulator (SOI) substrate.

These gate stacks 104 are arranged in the memory cell array region of the substrate 102 and function as memory cells and/or select transistors of a flash memory device (such as NAND or NOR flash memory). The flash memory 100 may include other device regions, such as a peripheral circuit region.

Each of the gate stacks 104 includes a tunneling oxide 106, a first semiconductor layer 108, an inter-gate dielectric layer 110, a second semiconductor layer 112, a metal layer 114, and a mask layer 116 sequentially formed on substrate 102. The tunneling oxide 106 may be made of silicon oxide. The first semiconductor layer 108 and the second semiconductor layer 112 may include doped polysilicon material. The first semiconductor layer 108 can be configured as the floating gate of a memory cell, while the second semiconductor layer 112 can be configured as the control gate of the memory cell. The metal layer 114 can be configured as the word line of the memory cell. The inter-gate dielectric layer 110 may be a tri-layer structure including oxide-nitride-oxide (ONO). The metal layer 114 may include tungsten (W), titanium (Ti), tantalum (Ta), tungsten nitride (WN), titanium nitride (TiN), or tantalum nitride (TaN). The mask layer 116 may be made of dielectric material, such as silicon nitride (SiN), silicon oxynitride (SiON), silicon oxide (SiO), other suitable materials, and/or combinations thereof.

The formation of the gate stacks 104 may include sequentially depositing materials for the tunnel oxide 106, the first semiconductor layer 108, the inter-gate dielectric layer 110, the second semiconductor layer 112, the metal layer 114, and the mask layer 116, followed by etching the stacked materials to form trenches 118.

Due to the characteristics of the etching process, the trench 118 tend to have a profile with a top width that is greater than the bottom width. Furthermore, due to the difference in etching selectivity between the metal material and the semiconductor material, the width of the bottom surface of the metal layer 114 is greater than the width of the top surface of the second semiconductor layer 112. The trench 118 may have a width D1181 at the top surface of the metal layer 114 and a width D1182 at the bottom surface of the metal layer 114, where the width D1182 is less than the width D1181. In other words, the spacing between the bottom surfaces of the adjacent word lines is less than the spacing between the top surfaces of the adjacent word lines. The trench 118 has a width D1183 at the top surface of the second semiconductor layer 112 and a width D1184 at the bottom surface of the tunnel oxide 106, where the width D1184 is less than the widths D1183. The width D1183 is greater than the width D1182. In other words, the spacing between adjacent tunnel oxides 106 is less than the spacing between adjacent control gates. The spacing between adjacent control gates is greater than the spacing between bottom surfaces of the adjacent word lines. As used herein, the word “width” refers to a measurement of a feature in a horizontal direction parallel to the main surface of the substrate 102 in a cross-sectional view at a specific location.

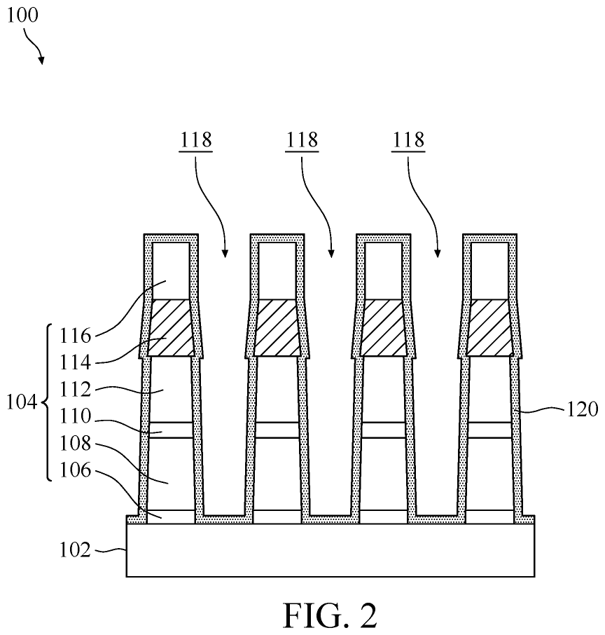

Next, as shown in FIG. 2, a first spacer layer 120 is conformally formed on the gate stacks 104. The first spacer layer 120 is conformally deposited on the top surface and the sidewalls of the gate stacks 104 and covers the bottoms of the trenches 118. In some embodiments, the first spacer layer 120 is made of dielectric materials such as silicon oxide (SiO), silicon oxynitride (SiON), silicon nitride (SiN), other suitable materials, and/or combinations thereof. The deposition process may include chemical vapor deposition (CVD), atomic layer deposition (ALD), or other suitable techniques.

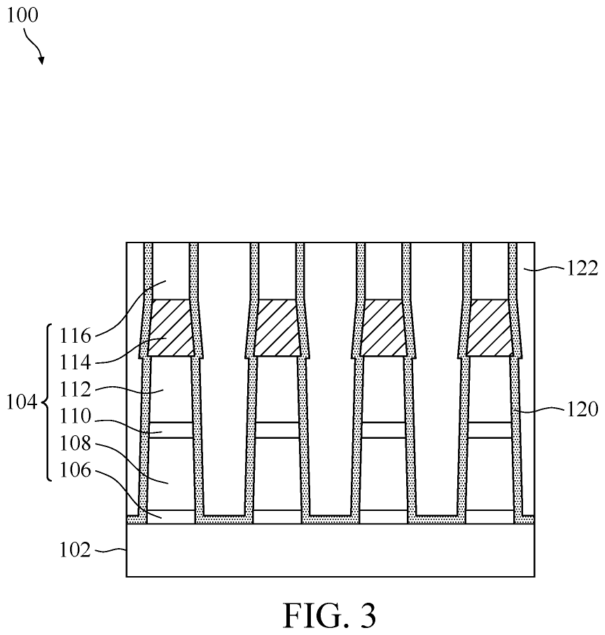

Then, as shown in FIG. 3, a sacrificial layer 122 is formed on the first spacer layer 120 to overfill the trenches 118. Subsequently, a planarization process is performed to remove excess sacrificial layer 122 and portions of the first spacer layer 120 on the top surfaces of the gate stacks 104, until the mask layer 116 is exposed. As a result, the top surface of the sacrificial layer 122 and the top surface of the mask layer 116 are coplanar. In some embodiments, the sacrificial layer 122 is made of semiconductor materials such as polysilicon. The formation of the sacrificial layer 122 may include CVD process. The planarization process may be chemical mechanical polishing (CMP) or etch-back process.

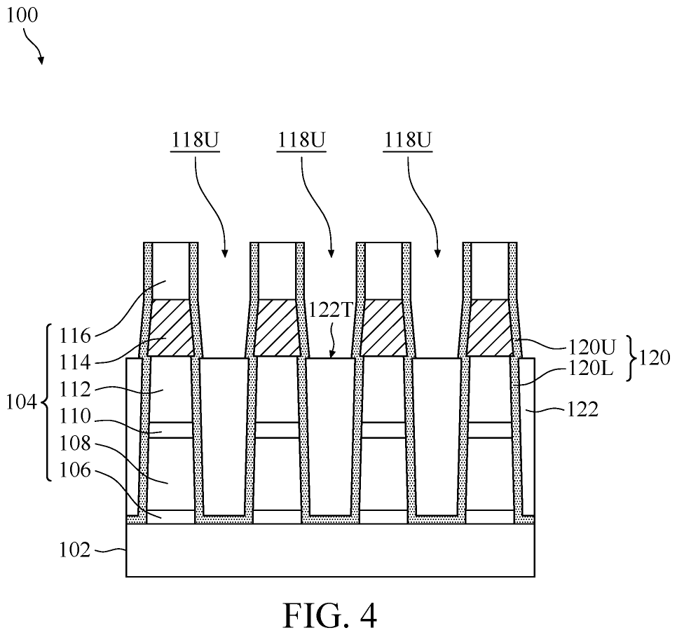

Next, as shown in FIG. 4, the sacrificial layer 122 is recessed using an etching process until the top surface 122T of the recessed sacrificial layer 122 is substantially level with or slightly below the top surface of the second semiconductor layer 112, thereby forming a shallow trench 118U on the recessed sacrificial layer 122. The portions of the first spacer layer 120 above the top surface 122T of the recessed sacrificial layer 122 are defined as upper portions 120U of the first spacer layer 120, and the portions of the first spacer layer 120 below the top surface 122T of the recessed sacrificial layer 122 are defined as lower portions 120L of the first spacer layer 120. The portion of the gate stack 104 above the top surface 122T of the sacrificial layer 122 is defined as upper portion of the gate stack 104, and the portion of the gate stack 104 below the top surface 122T of the sacrificial layer 122 is defined as lower portion of the gate stack 104. In some embodiments, the upper portion of the gate stack 104 may include the metal layer 114 and the mask layer 116, while the lower portion of the gate stack 104 may include the tunnel oxide 106, the first semiconductor layer 108, the inter-gate dielectric layer 110, and the second semiconductor layer 112. The upper portions 120U of the first spacer layer 120 are formed alongside the sidewalls of the upper portions of the gate stacks 104, and the shallow trench 118U exposes the upper portion 120U of the first spacer layer 120. The lower portions 120L of the first spacer layer 120 are formed alongside the sidewalls of the lower portions of the gate stacks 104, and on the exposed surface of the substrate 102. The recessed sacrificial layer 122 covers the lower portion 120L of the first spacer layer 120. In some embodiment, the etching process has a significantly higher selectivity for the sacrificial layer 122 compared to the first spacer layer 120 and the mask layer 116, which may avoid loss of the first spacer layer 120 and the mask layer 116.

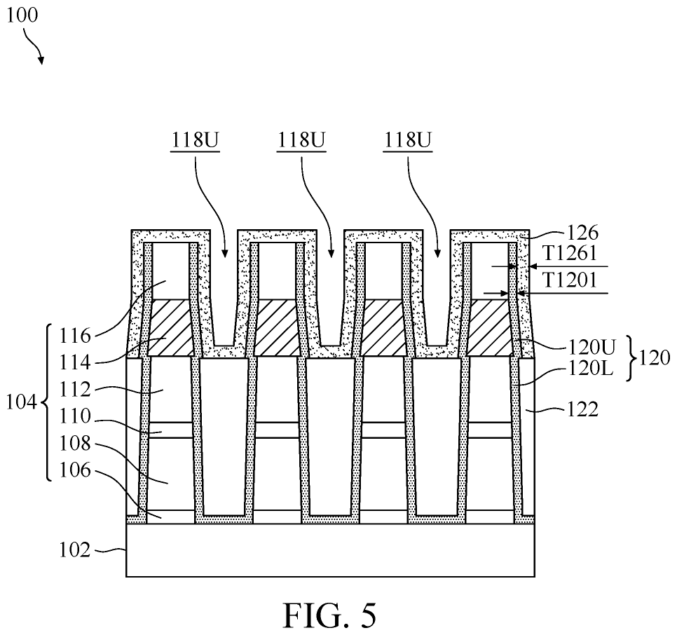

Next, as shown in FIG. 5, a second spacer layer 126 is conformally formed on the sacrificial layer 122, the first spacer layer 120, and the mask layer 116. In some embodiments, the second spacer layer 126 is made of dielectric materials such as silicon nitride (SiN), silicon oxynitride (SiON), silicon oxide (SiO), other suitable materials, and/or combinations thereof. In some embodiments, the second spacer layer 126 and the first spacer layer 120 are made of different materials. For example, the first spacer layer 120 may be an oxide layer, and the second spacer layer 126 may be a nitride layer. In some embodiments, the first spacer layer 120 (made of oxide) can reduce the negative impact (e.g., higher compressive stress) caused by the second spacer layer 126 (made of nitride) on the metal layer 114. The second spacer layer 126 is used to protect the upper portions 120U of the first spacer layer 120. The deposition process may include CVD or ALD process.

In some embodiments, the first spacer layer 120 has a thickness T1201 along the sidewall of the gate stack 104, while the second spacer layer 126 has a thickness T1261 along the sidewall of the gate stack 104. The thickness T1261 of the second spacer layer 126 can be substantially equal to the thickness T1201 of the first spacer layer 120, for example, with a difference of within about 20% of the thickness T1201.

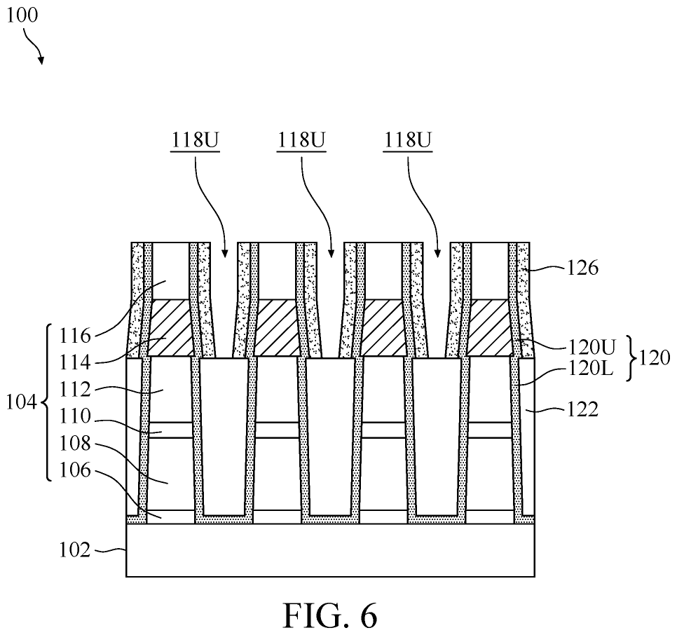

Next, as shown in FIG. 6, the horizontal portion of the second spacer layer 126 is removed using an etching process to expose the top surface of the sacrificial layer 122 and the mask layer 116. After the etching process, the remaining second spacer layer 126 covers the upper portions 120U of the first spacer layer 120. In some embodiments, a dry etching process may be used to remove the horizontal portion of the second spacer layer 126.

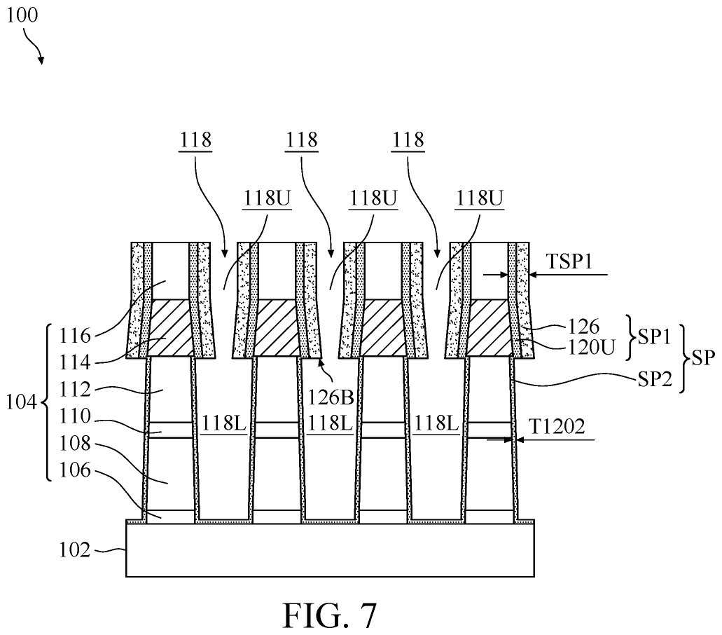

Next, as shown in FIG. 7, the sacrificial layer 122 is removed using an etching process until the lower portions 120L of the first spacer layer 120 are exposed, thereby forming a lower trench 118L which is in connection with the shallow trench 118U. The lower trench 118L also exposes the bottom surface 126B of the second spacer layer 126. The bottom surface 126B may be substantially level with or slightly below the top surface of the second semiconductor layer 112. In some embodiments, the etching process is a wet etching process using diluted hydrofluoric acid (dHf). During the etching process, the lower portions 120L of the first spacer layer 120 may be further thinned to enlarge the size of the lower trench 118L. In some embodiments, the upper portions 120U of the first spacer layer 120 covered by the second spacer layer 126 remain substantially unetched. In other words, the thickness T1202 of the thinned lower portion 120L (also referred to as thin spacer SP2) of the first spacer layer 120 is less than the thickness T1201 of the upper portion 120U of the first spacer layer 120.

A spacer structure SP including the remaining second spacer layer 126 and the remaining first spacer layer 120 is formed, in which the spacer structure SP covers the sidewalls of the gate stacks 104. The spacer structure SP includes thick spacers SP1 formed by the upper portions 120U of the first spacer layer 120 and the second spacer layer 126, and a thin spacer SP2 formed by the thinned lower portions 120L of the first spacer layer 120. The thick spacers SP1 cover the upper portions of the gate stacks 104 (including the mask layer 116 and the metal layer 114) to facilitate subsequent seal process of the trenches 118. The thin spacers SP2 cover the lower portions of the gate stacks 104 (including the tunnel oxide 106, the first semiconductor layer 108, the inter-gate dielectric layer 110, and the second semiconductor layer 112) to assist in forming air gaps with larger volume.

The thick spacer SP1 has a thickness TSP1 along the sidewall of the gate stack 104, which is substantially equal to the sum of the thickness T1201 and the thickness T1261. The thin spacer SP2 has a thickness T1202 along the sidewall of the gate stack 104. In some embodiments, the ratio (T1202/T1201) of the thickness T1202 to the thickness T1201 is about 0.1 to 0.6, and the ratio (T1202/TSP1) of the thickness T1202 to the thickness TSP1 is about 0.05 to 0.5. This may further avoid damage to the semiconductor layers 108 and 112 of the gate stack 104 by the etching processes, and may increase the volume of the subsequently formed air gap, thereby improving the reliability of the memory cell and reducing capacitance between adjacent gate stacks 104.

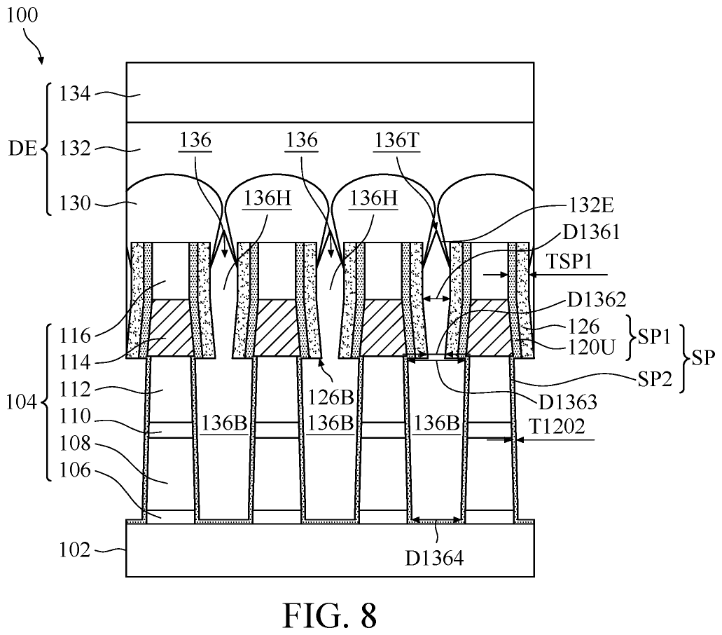

Next, as shown in FIG. 8, a dielectric structure DE is formed over the spacer structure SP to seal the trenches 118, thereby forming air gaps 136. Each of the air gaps 136 includes a head portion 136H and a body portion 136B. The head portion 136H is formed from the shallow trench 118U and is located between the thick spacers SP1. The body portion 136B is formed from the lower trench 118L and is located between the thin spacers SP2.

The dielectric structure DE includes a first dielectric layer 130, a second dielectric layer 132, and a third dielectric layer 134. The first dielectric layer 130 may have multiple separated dielectric patterns formed on the spacer structure SP corresponding to each gate stacks 104 using an isotropic deposition process such as plasma-enhanced chemical vapor deposition. In other embodiments, adjacent dielectric patterns of the first dielectric layer 130 may be merged into a continuous pattern. In some embodiments, the first dielectric layer 130 is made of an oxide, such as silicon oxide.

The characteristics of the isotropic deposition process cause the first dielectric layer 130 to have overhang profiles. The presence of the thick spacers SP1 in the shallow trenches 118U and the overhang profiles of the first dielectric layer 130 contributes to sealing the shallow trenches 118U in a shorter deposition time. The shorter deposition time may also reduce the amount of material of the first dielectric layer 130 deposited into the lower trenches 118L, thus preventing a reduction in volume of the lower trenches 118L (i.e., the body portions 136B of the air gaps 136). Additionally, the overhang profiles results in a pointed tips 136T for the head portions 136H. The pointed tip 136T is located at a higher position than the top surface of the spacer structure SP and the top surface of the gate stacks 104.

The second dielectric layer 132 is formed over the first dielectric layer 130. In embodiments where the first dielectric layer 130 has separated dielectric patterns, the second dielectric layer 132 includes portions 132E that extend between adjacent dielectric patterns of the first dielectric layer 130, thereby sealing the trenches 118. In some embodiments, the second dielectric layer 132 is made of a nitride, such as silicon nitride. The third dielectric layer 134 is formed over the second dielectric layer 132. In some embodiments, the first dielectric layer 130 is made of an oxide, such as silicon oxide.

The head portion 136H has a spindle-shaped profile. Specifically, the width of the head portion 136H tapers from its middle height upward towards the pointed tip 136T, and tapers downward towards its bottom. The head portion 136H has a width D1361 at its middle height (e.g., at the position of the top surface of the metal layer 114), and a width D1362 at its bottom (e.g., near the bottom surface of the metal layer 114). The width D1362 is less than the width D1361. The width D1361 can be the maximum width of the head portion 136H. The ratio of the width D1362 to the width D1361 ranges from about 0.2 to about 0.9. In preferred embodiments, the ratio of the width D1362 to the width D1361 ranges from about 0.2 to about 0.7.

The width of the body portion 136B tapers downward from its top towards its bottom. The body portion 136B has a width D1363 at its top (e.g., near the position of the top surface of the second semiconductor layer 112) and a width D1364 at its bottom (e.g., near the position of the bottom surface of the tunnel oxide 106). The width D1364 is less than the width D1363. The width D1363 can be the maximum width of the air gap 136. The ratio of the width D1364 to the width D1363 ranges from about 0.2 to about 0.9.

Overall, the body portion 136B of the air gap 136 is wider than the head portion 136H of the air gap 136. The width D1363 is greater than both the widths D1361 and D1362. For example, the ratio of the width D1361 to the width D1363 ranges from about 0.2 to about 0.6. The width D1364 can be greater than both the widths D1361 and D1362. For example, the ratio of the width D1361 to the width D1364 ranges from about 0.3 to about 0.9.

Due to the larger volume of the body portion 136B of the air gap 136, there is a lower capacitance between adjacent first semiconductor layers 108 (i.e., floating gates) of the neighboring gate stacks 104. Thus, this may mitigate the coupling effect between floating gates (FG-FG coupling) and improve data retention capability of memory cells, thereby enhancing the performance of the resulting semiconductor memory device in final electrical testing. In some embodiments, additional known components may be formed over the semiconductor structure 100 in FIG. 8 to complete a flash memory device, such as a NAND-type flash memory device.

As described above, by forming the thin spacers SP2 on the lower sidewalls of the gate stacks 104, the size of the lower trenches 118L is expanded. The thick spacers SP1 are formed along the upper portions of the gate stacks 104 to facilitate the sealing of the shallow trenches 118U, and prevent the volume reduction of the lower trenches 118L during subsequent deposition processes. Therefore, the body portion 136B of the air gap 136 can be formed with a larger volume, thereby improving the performance of the resulting semiconductor memory device.

Furthermore, the flash memory of the present disclosure may be used on automotive electronics, such as Advanced Driver Assistance Systems (ADAS), Instrument Clusters, Infotainment. The flash memory of the present disclosure may be used on space constrained applications including Wearable, MP3 players, smart watches, games, digital radio, toys, cameras, digital photo album, GPS, Bluetooth and WiFi modules. The flash memory of the present disclosure may be used on IoT and mobile electronic devices.

The present invention is suitable for making miniaturized flash memory, so as to increase the total number of dies on a wafer. Therefore, the production cost and energy consumption of manufacturing a single IC are reduced, and the production energy consumption of subsequent packaging is also reduced, thereby reducing carbon emissions in the process of producing flash memory. Besides, since reliability and durability of the flash memory device of the present invention are improved, the present invention provides a sustainable flash memory.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A flash memory, comprising:
multiple gate stacks arranged on a substrate;
a spacer structure comprising multiple thin spacers covering sidewalls of lower portions of the gate stacks and multiple thick spacers covering sidewalls of upper portions of the gate stacks, wherein the thick spacers are located over the respective thin spacers, and the thick spacers are thicker than the thin spacers, wherein the thick spacers comprise upper portions of a first spacer layer and second spacer layers, the thin spacers comprise lower portions of the first spacer layer, and the lower portions of the first spacer layer are thinner than the upper portions of the first spacer layer;
a dielectric structure disposed on the spacer structure; and
an air gap sealed by the dielectric structure and the spacer structure, wherein the air gap comprises a body portion between the thin spacers and a head portion between the thick spacers, and the body portion is wider than the head portion.

2. The flash memory as claimed in claim 1, wherein the head portion of the air gap has:
a first width at a middle height of the head portion; and
a second width at bottoms of the thick spacers, wherein the second width is less than the first width.

3. The flash memory as claimed in claim 2, wherein the body portion of the air gap has a third width at tops of the thin spacers, and the third width is greater than the first width.

4. The flash memory as claimed in claim 2, wherein the body portion of the air gap has a fourth width at bottoms of the thin spacers, and the fourth width is greater than the first width.

5. The flash memory as claimed in claim 1, wherein the head portion of the air gap has a pointed tip, and a width of the head portion of the air gap tapers from a middle height of the head portion upward towards the pointed tip.

6. The flash memory as claimed in claim 1, wherein the first spacer layer is made of different material than the second spacer layers.

7. The flash memory as claimed in claim 6, wherein bottom surfaces of the second spacer layers are exposed from the body portion of the air gap.

8. The flash memory as claimed in claim 6, wherein each of the gate stacks comprises, in sequence stacked over the substrate, a tunnel oxide layer, a first semiconductor layer, an inter-gate dielectric layer, a second semiconductor layer, a metal layer and a masking layer, and a width of a bottom surface of the metal layer is greater than a width of a top surface of the second semiconductor layer.

9. The flash memory as claimed in claim 1, wherein the lower portion of each of the gate stacks comprises a tunnel oxide layer over the substrate, a first semiconductor layer over the tunnel oxide layer, an inter-gate dielectric layer over the first semiconductor layer, and a second semiconductor layer over the inter-gate dielectric layer.

10. The flash memory as claimed in claim 9, wherein the upper portion of each of the gate stacks comprises a metal layer over the second semiconductor layer and a masking layer over the metal layer.

11. A method for forming a flash memory, comprising:
forming multiple gate stacks over a substrate;
conformally forming a first spacer layer on sidewalls of the gate stacks;
forming a sacrificial layer to partially fill a trench between the gate stacks and cover a lower portion of the first spacer layer;
forming a second spacer layer to cover an upper portion of the first spacer layer and an upper surface of the sacrificial layer;
removing a horizontal portion of the second spacer layer covering the upper surface of the sacrificial layer;
completely removing the sacrificial layer;
partially removing the lower portion of the first spacer layer to form a thin spacer; and
forming a dielectric structure on a top surface of the first spacer layer and a top surface of the second spacer layer, wherein the trench is sealed by the dielectric structure to form an air gap.

12. The method for forming the flash memory as claimed in claim 11, wherein, when the sacrificial layer is completely removed, sidewalls of the upper portion of the first spacer layer are covered by the second spacer layer, and after the sacrificial layer is completely removed, the lower portion of the first spacer layer is exposed.

13. The method for forming the flash memory as claimed in claim 11, wherein a head portion of the air gap has a pointed tip, and a width of the head portion of the air gap tapers from a middle height of the head portion upward towards the pointed tip.

14. The method for forming the flash memory as claimed in claim 11, wherein each of the gate stacks comprises, in sequence stacked over the substrate, a tunnel oxide layer, a first semiconductor layer, an inter-gate dielectric layer, a second semiconductor layer, a metal layer, and a masking layer.

15. The method for forming the flash memory as claimed in claim 14, wherein the upper surface of the sacrificial layer is not higher than a top surface of the second semiconductor layer.

16. The method for forming the flash memory as claimed in claim 14, wherein a width of a bottom surface of the metal layer is greater than a width of a top surface of the second semiconductor layer.

17. The method for forming the flash memory as claimed in claim 14, wherein forming the sacrificial layer comprises:
depositing a semiconductor material to overfill the trench between the gate stacks;
removing a portion of the semiconductor material above the gate stacks until the masking layer is exposed; and
recessing the semiconductor material.

18. The method for forming the flash memory as claimed in claim 11, wherein forming the dielectric structure comprises:
forming multiple first dielectric layers on the first spacer layer and the second spacer layer and respectively corresponding to the gate stacks; and
forming a second dielectric layer on the first dielectric layers, wherein the second dielectric layer is made of a different material than the first dielectric layers.

19. The method for forming the flash memory as claimed in claim 18, wherein the second dielectric layer comprises an extension portion between the first dielectric layers.

20. The method for forming the flash memory as claimed in claim 19, wherein a surface of the extension portion of the second dielectric layer is exposed from the air gap.
